(19) United States
(12) Patent Application Publication
(10) Pub. No.: US 2023/0063473 A1
(43) Pub. Date: Mar. 2, 2023

(54) SEMICONDUCTOR STRUCTURE AND METHOD FOR MANUFACTURING SAME

(71) Applicants: CHANGXIN MEMORY TECHNOLOGIES, INC., Hefei City (CN); Beijing Superstring Academy of Memory Technology, Beijing (CN)

(72) Inventors: Guangsu SHAO, Hefei (CN); Deyuan XIAO, Hefei (CN); Yunsong QIU, Hefei (CN)

(21) Appl. No.: 17/750,458

(22) Filed: May 23, 2022

(30) Foreign Application Priority Data
Aug. 25, 2021 (CN) 202110980473.2

(51) Int. Cl. H01L 21/762; H01L 21/768; H01L 21/304

(52) U.S. Cl. CPC H01L 21/76224; H01L 21/76877; H01L 21/3043

(57) ABSTRACT

Provided is a method for manufacturing a semiconductor structure. It includes: forming first grooves filled with a first dielectric layer and extending in a first direction in a substrate; forming second grooves extending in a second direction in the substrate and the first dielectric layer, the second grooves and the first grooves being intersected and defining discrete active columns in the substrate; depositing second dielectric layers on sidewalls of the second grooves; depositing sacrificial layers in the second grooves, the sacrificial layers being sandwiched between the second dielectric layers; removing part of the first dielectric layer and part of the second dielectric layer, and forming hole structures extending in the second direction, the hole structures surrounding the active columns, and adjacent hole structures being separated by the sacrificial layers; forming word lines in the hole structures; and removing the sacrificial layers to form air gaps between adjacent word lines.

### CROSS-REFERENCE TO RELATED APPLICATIONS

This application is filed based upon and claims priority to Chinese Patent Application No. 202110980473.2, filed on Aug. 25, 2021, the contents of which are hereby incorporated by reference in its entirety.

### BACKGROUND

A semiconductor device, such as a memory, includes multiple word lines disposed adjacent to each other, and the adjacent word lines are separated by a dielectric layer.

### SUMMARY

In view of this, embodiments of the disclosure provide a semiconductor structure and a method for manufacturing the same, to resolve at least one problem in the background.

The disclosure relates to the field of semiconductor manufacturing, and in particular, to a semiconductor structure and a method for manufacturing the same.

An embodiment of the disclosure provides a method for manufacturing a semiconductor structure. The method includes the following operations.

Multiple first grooves filled with a first dielectric layer and extending in a first direction are formed in a substrate.

Multiple second grooves extending in a second direction are formed in the substrate and the first dielectric layer. The second grooves and the first grooves are intersected, and define multiple discrete active columns in the substrate.

Second dielectric layers are deposited on sidewalls of the second grooves.

Sacrificial layers are deposited in the second grooves. The sacrificial layers are sandwiched between the second dielectric layers.

Part of the first dielectric layer and part of the second dielectric layer are removed, to form multiple hole structures extending in the second direction. The hole structures surround the active columns. Adjacent hole structures are separated by the sacrificial layers.

Word lines are formed in the hole structures.

The sacrificial layers are removed to form air gaps between the adjacent word lines.

An embodiment of the disclosure further provides a semiconductor structure, including a substrate, a first dielectric layer, a second dielectric layer, air gaps, and multiple word lines.

The substrate includes multiple first grooves extending in a first direction and multiple second grooves extending in a second direction. The first grooves and the second grooves are intersected and define multiple discrete active columns in the substrate.

The first dielectric layer is located at a bottom of first grooves.

The second dielectric layers cover a sidewall at a bottom of the second grooves.

The air gaps are located in the second grooves.

The multiple word lines extend in the second direction, and are located in the first groove and the second groove. The word lines surround the active columns and cover upper surfaces of the first dielectric layer and the second dielectric layers.

The adjacent word lines are separated by the air gaps.

### BRIEF DESCRIPTION OF THE DRAWINGS

FIG. 1 is a block flowchart of a method for manufacturing a semiconductor structure according to an embodiment of the disclosure.

FIG. 2 is a schematic top view of a semiconductor structure according to an embodiment of the disclosure.

FIG. 3A to FIG. 15D are process flow diagrams of a semiconductor structure according to an embodiment of the disclosure.

### DETAILED DESCRIPTION

Exemplary embodiments disclosed in the present application are described in more detail with reference to drawings. Although the exemplary embodiments of the disclosure are shown in the drawings, it should be understood that the disclosure may be implemented in various forms and should not be limited by the specific embodiments described here. On the contrary, these embodiments are provided for more thorough understanding of the disclosure, and to fully convey a scope disclosed in the embodiments of the disclosure to a person skilled in the art.

In the following descriptions, a lot of specific details are given in order to provide the more thorough understanding of the disclosure. However, it is apparent to a person skilled in the art that the disclosure may be implemented without one or more of these details. In other examples, in order to avoid confusion with the disclosure, some technical features well-known in the field are not described. Namely, all the features of the actual embodiments are not described here, and well-known functions and structures are not described in detail.

In the drawings, the sizes of a layer, a region, and an element and their relative sizes may be exaggerated for clarity. The same reference numeral represents the same element throughout.

It should be understood that while the element or the layer is referred to as being “on”, “adjacent to”, “connected to” or “coupled to” other elements or layers, it may be directly on the other elements or layers, adjacent to, connected or coupled to the other elements or layers, or an intermediate element or layer may be existent. In contrast, while the element is referred to as being “directly on”, “directly adjacent to”, “directly connected to” or “directly coupled to” other elements or layers, the intermediate element or layer is not existent. It should be understood that although terms first, second, third and the like may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teaching of the disclosure, a first element, component, region, layer or section discussed below may be represented as a second element, component, region, layer or section. While the second element, component, region, layer or section is discussed, it does not mean that the first element, component, region, layer or section is necessarily existent in the disclosure.

Spatial relation terms, such as “under”, “below”, “lower”, “underneath”, “above”, “upper” and the like, may be used here for conveniently describing so that a relationship between one element or feature shown in the drawings and other elements or features is described. It should be understood that in addition to orientations shown in the drawings, the spatial relationship terms are intended to further include the different orientations of a device in use and operation. For example, if the device in the drawings is turned over, then the elements or the features described as “below” or “underneath” or “under” other elements may be oriented “on” the other elements or features. Therefore, the exemplary terms “below” and “under” may include two orientations of up and down. The device may be otherwise oriented (rotated by 90 degrees or other orientations) and the spatial descriptions used here are interpreted accordingly.

A purpose of the terms used here is only to describe the specific embodiments and not as limitation to the disclosure. While used here, singular forms of “a”, “an” and “said/the” are also intended to include plural forms, unless the context clearly indicates another mode. It should also be understood that terms “is comprised of” and/or “including”, while used in the description, determine the existence of the described features, integers, steps, operations, elements and/or components, but do not exclude the existence or addition of one or more other features, integers, steps, operations, elements, components, and/or groups. As used herein, a term “and/or” includes any and all combinations of related items listed.

The inventors realized that, the dielectric constant of the dielectric layer is relatively large, so that there is a large parasitic capacitance between adjacent word lines, which affects the operation speed of the semiconductor device.

A Dynamic Random Access Memory (DRAM) having a vertical transistor provided in the related art includes multiple word lines extending in a same direction. The adjacent word lines are separated by a dielectric layer. However, the dielectric layer has a relatively large dielectric constant, so that there is a relatively large dielectric constant between the adjacent word lines. The dielectric constant can reduce an access speed of data, which affects the performance of the DRAM.

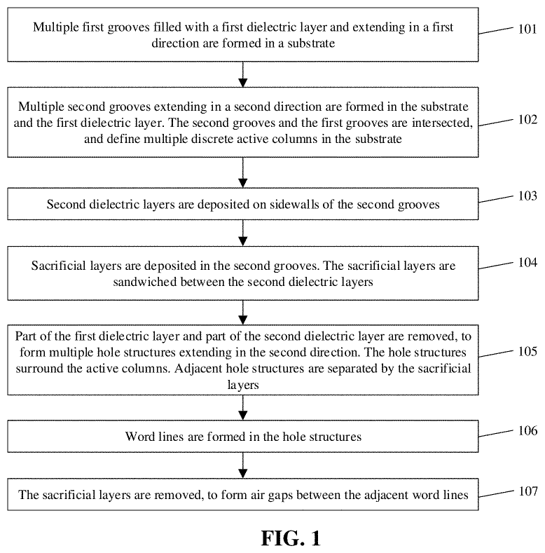

Based on this, an embodiment of the disclosure provides a method for manufacturing a semiconductor structure; details are shown in FIG. 1. As shown in the figure, the method includes the following steps.

At S101, multiple first grooves filled with a first dielectric layer and extending in a first direction are formed in a substrate.

At S102, multiple second grooves extending in a second direction are formed in the substrate and the first dielectric layer. The second grooves and the first grooves are intersected, and define multiple discrete active columns in the substrate.

At S103, second dielectric layers are deposited on sidewalls of the second grooves.

At S104, sacrificial layers are deposited in the second grooves. The sacrificial layers are sandwiched between the second dielectric layers.

At S105, part of the first dielectric layer and part of the second dielectric layer are removed, to form multiple hole structures extending in the second direction. The hole structures surround the active columns. Adjacent hole structures are separated by the sacrificial layers.

At S106, word lines are formed in the hole structures.

At S107, the sacrificial layers are removed, to form air gaps between the adjacent word lines.

According to the method for manufacturing a semiconductor structure provided in the embodiments of the disclosure, the air gaps having a relatively low dielectric constant are formed between the adjacent word lines, which can reduce a parasitic capacitance between the adjacent word lines in the semiconductor structure, so that the performance of the semiconductor structure can be improved.

The method for manufacturing a semiconductor structure provided in the embodiments of the disclosure may be used for forming a DRAM, but is not limited thereto. Any semiconductor structures having Vertical Gate All Around (VGAA) may be manufactured by using the method provided by the embodiments of the disclosure.

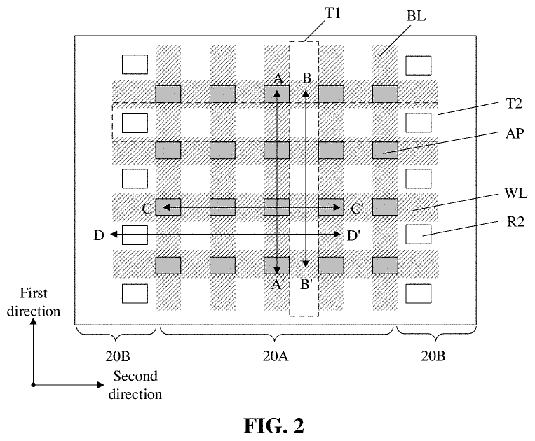

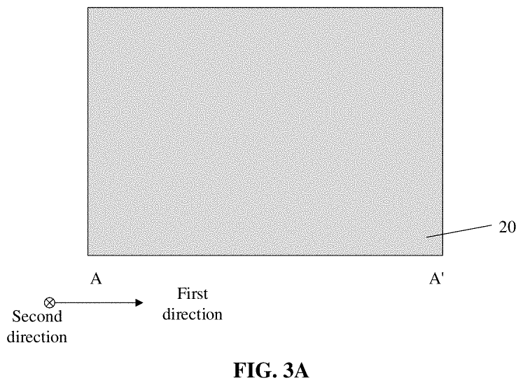

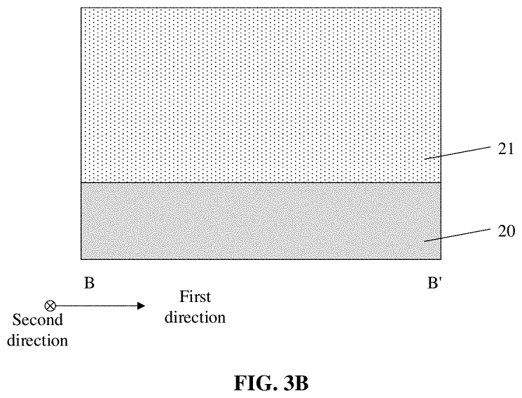

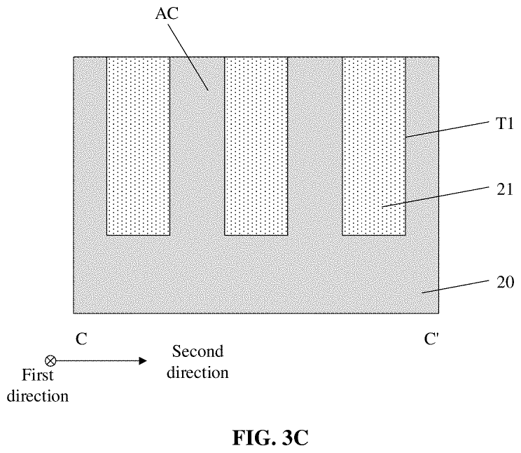

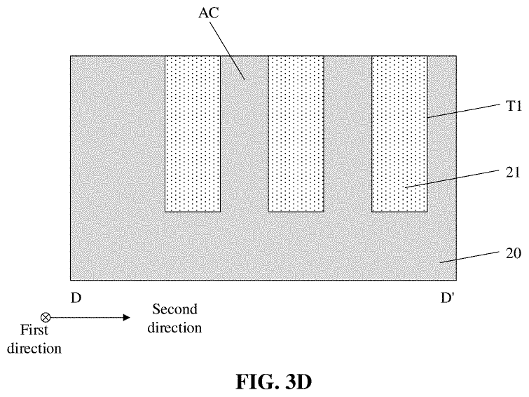

FIG. 2 is a schematic top view of a semiconductor structure according to an embodiment of the disclosure. FIG. 3A to FIG. 15D are process flow diagrams of a semiconductor structure according to an embodiment of the disclosure. FIG. 3A to FIG. 15A are schematic diagrams of cross-sectional structures of each process step taken along a line AA′ of FIG. 2. FIG. 3B to FIG. 15B are schematic diagrams of cross-sectional structures of each process step taken along a line BB′ of FIG. 2. FIG. 3C to FIG. 15C are schematic diagrams of cross-sectional structures of each process step taken along a line CC′ of FIG. 2. FIG. 3D to FIG. 15D are schematic diagrams of cross-sectional structures of each process step taken along a line DD′ of FIG. 2. The method for manufacturing a semiconductor structure according to the embodiments of the disclosure is further described in detail below with reference to the accompanying drawings. While the embodiments of the disclosure are described in detail, for ease of descriptions, a schematic diagram may not be partially enlarged according to a general scale, and the schematic diagram is only an example, it should not limit a scope of protection of the disclosure herein.

First, S101 is performed; multiple first grooves T1 filled with a first dielectric layer 21 and extending in a first direction are formed in a substrate 20, as shown in FIGS. 3A to 3D.

The substrate may be a semiconductor substrate, and may include at least one elementary semiconductor material (for example, a silicon (Si) substrate, or a germanium (Ge) substrate), at least one III-V compound semiconductor material, at least one II-VI compound semiconductor material, at least one organic semiconductor material, or other semiconductor materials known in the art. In a specific embodiment, the substrate is the Si substrate. The Si substrate may or may not be doped.

Specifically, the operation that multiple first grooves T1 filled with a first dielectric layer 21 and extending in a first direction are formed in a substrate 20 includes: the multiple first grooves T1 extending in the first direction is formed by performing an etching process on the substrate 20; and the first dielectric layer 21 is filled in the first grooves T1.

The etching process includes, but is not limited to, a Self-Aligned Double Patterning (SADP) process, or a Self-Aligned Quadruple Patterning (SAQP) process. In some embodiments, the multiple first grooves T1 are equidistantly distributed in the substrate 20.

In an embodiment, a material of the first dielectric layer 21 includes oxides, such as silicon oxide. The first dielectric layer 21 may be formed in the multiple first grooves T1 by using processes such as Atomic Layer Deposition (ALD), Chemical Vapor Deposition (CVD), and the like. Optionally, after the first dielectric layer 21 is formed in the first grooves T1, an upper surface of the first dielectric layer 21 may be coplanar with an upper surface of the substrate 20 by using a planarization process such as Chemical Mechanical Polishing (CMP) and/or an etching process.

Referring to FIG. 3C and FIG. 3D, the first grooves T1 define the substrate 20 into multiple structure bodies AC extending in the first direction. The adjacent structure bodies AC are separated by the first dielectric layer 21.

In an embodiment, the method further includes: a first source/drain doped area (not shown) and a second source/drain doped area (not shown) are respectively formed on tops and bottoms of the structure bodies AC by subjecting the substrate 20 with ion implantation.

Specifically, the subjecting the substrate with ion implantation includes: a first doped ion is implanted into the upper surface of the substrate, to form the first source/drain doped area on the tops of the structure bodies; and implanting a second doped ion into the lower surface of the substrate, to form the second source/drain doped area at the bottoms of the structure bodies. More specifically, the first doped ion is same as the second doped ion.

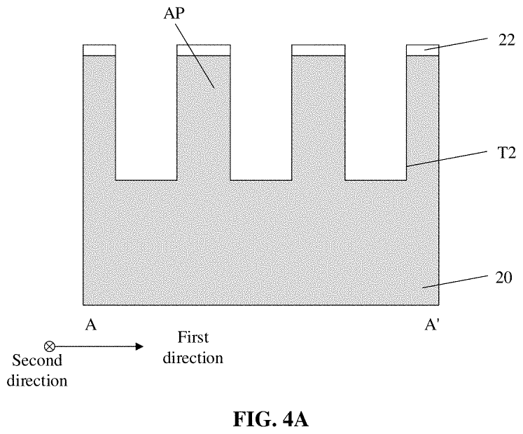

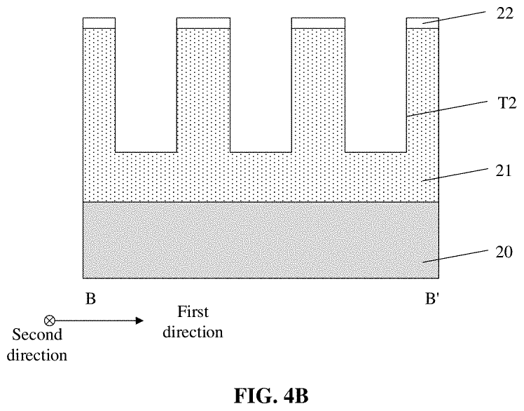

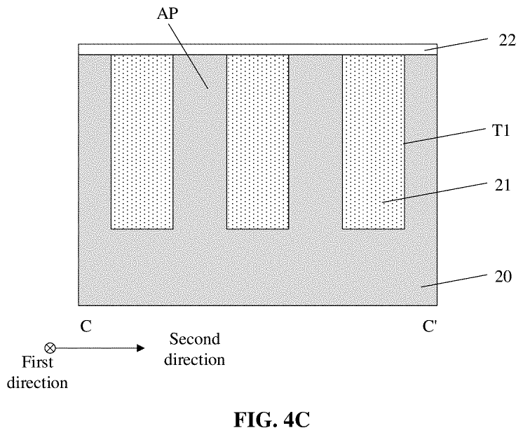

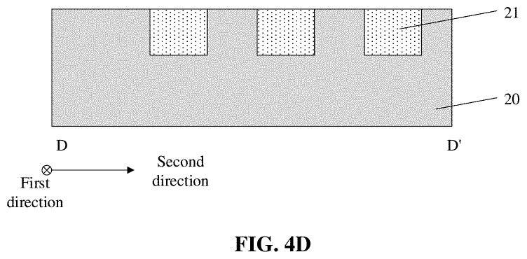

Next, S102 is performed; multiple second grooves T2 extending in a second direction are formed in the substrate 20 and the first dielectric layer 21. The second grooves T2 and the first grooves T1 are intersected, and define multiple discrete active columns AP in the substrate 20, as shown in FIGS. 4A to 4D.

A formation process of the second grooves T2 includes, but is not limited to, a Self-Aligned Double Patterning (SADP) process, or a Self-Aligned Quadruple Patterning (SAQP) process. In some embodiments, the multiple second grooves T2 are equidistantly distributed in the substrate 20.

In an embodiment, the first direction is perpendicular to the second direction, but is not limited thereto. In other embodiments, an acute angle is formed between the first direction and the second direction.

In an embodiment, the depths of the second grooves T2 are less than the depths of the first grooves T1. That is to say, the bottom surfaces of the second grooves T2 are higher than the bottom surfaces of the first grooves T1. In this way, the first dielectric layer 21 in the first grooves T1 has different heights in the extending direction. Specifically, the upper surface of the first dielectric layer 21 between the adjacent two active columns AP is flush with the upper surface of the substrate 20, as shown in FIG. 4C. The upper surface of the first dielectric layer 21 at an intersection of the first groove T1 and the second groove T2 is flush with the bottom surface of the second groove T2, as shown in FIG. 4D.

In some embodiments, the method further includes the following operation. A barrier layer 22 is formed on the substrate 20. The barrier layer 22 at least covers the upper surface of the active columns AP, and is configured to protect the top of the active columns AP from being oxidized, nitrided, damaged, or contaminated in subsequent processes. In a specific embodiment, before the operation that the substrate 20 and the first dielectric layer 21 are etched to form the second grooves T2, the barrier layer 22 covering the substrate 20 and the first dielectric layer 21 is formed. In an embodiment, a material of the barrier layer 22 may be oxide, specifically, silicon oxide. The barrier layer 22 may be formed by using processes such as ALD, CVD, and the like.

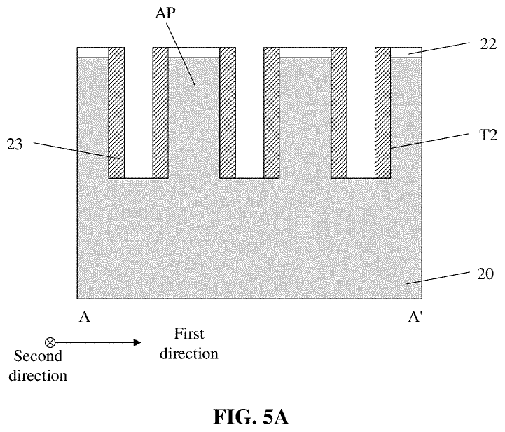

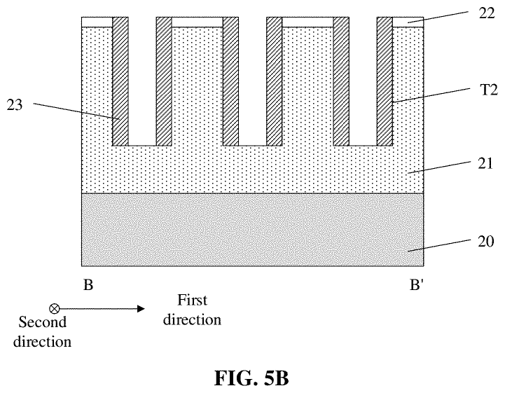

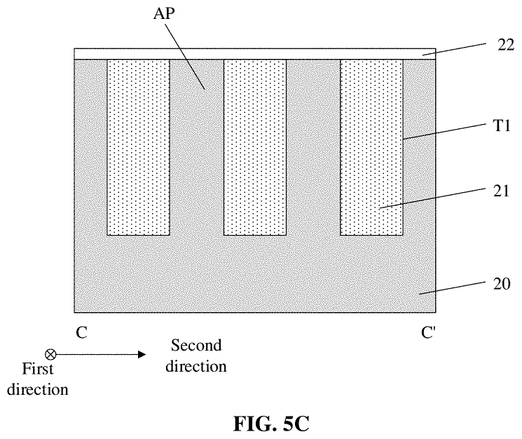

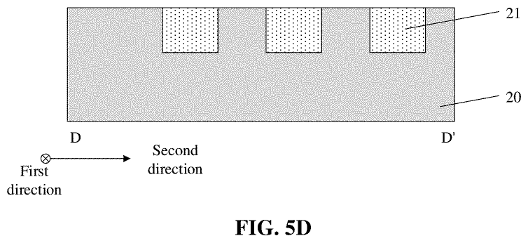

Next, S103 is performed; second dielectric layers 23 are deposited on sidewalls of the second grooves T2, as shown in FIGS. 5A to 5D.

In an embodiment, a material of the second dielectric layers 23 may be oxides, specifically, silicon oxide. The second dielectric layers 23 may be formed on exposed surfaces of the multiple second grooves T2 by using processes such as ALD, CVD, and the like. Optionally, after the operation that the second dielectric layers 23 are formed in the second grooves T2, a back-etching process may be used to remove the second dielectric layers 23 on the bottom surfaces of the second grooves T2, so that the substrate 20 is exposed from the bottoms of the second grooves T2. The second dielectric layers 23 are configured to protect sidewalls of the active columns AP from being oxidized, nitrided, damaged, or contaminated in subsequent processes.

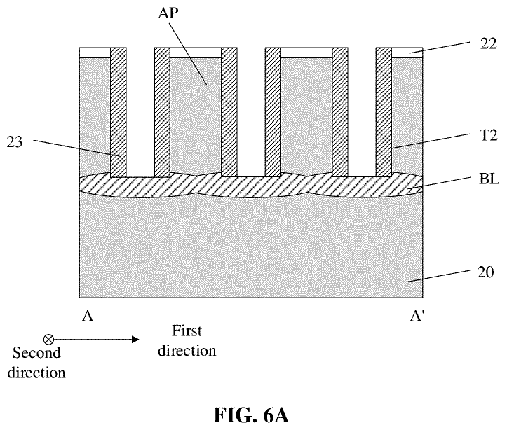

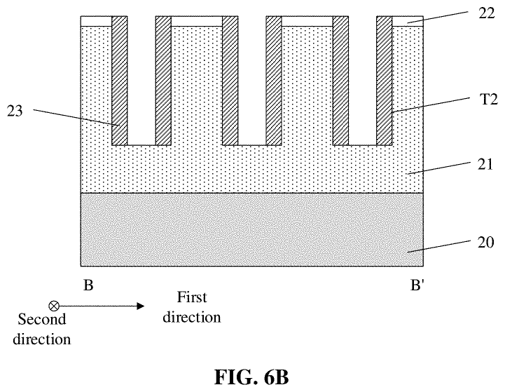

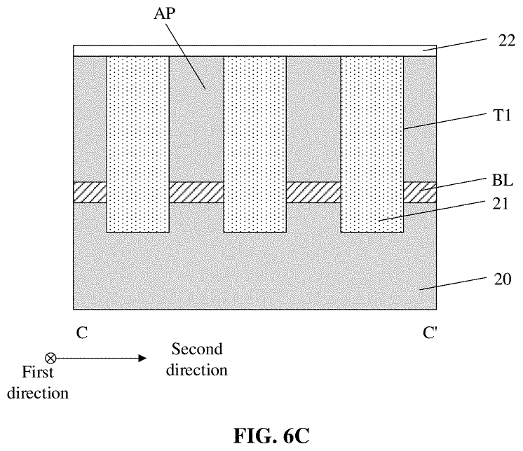

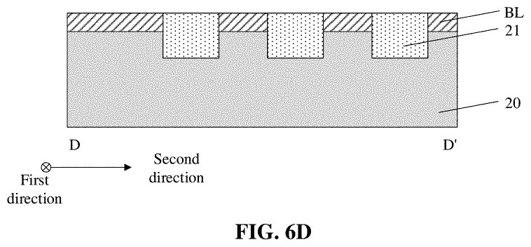

In an embodiment, after the second dielectric layers 23 are deposited on the sidewalls of the second grooves T2, the method further includes: the substrate 20 is doped from bottoms of the second grooves T2, to form multiple bit lines BL extending in the first direction. The adjacent bit lines BL are separated by the first dielectric layer 21, as shown in FIGS. 6A to 6D.

The second source/drain doped area extends from the lower surface of the substrate to the active column. At least part of the second source/drain doped area is located on the bottom surfaces of the second grooves. That is to say, at least part of the second source/drain doped area is located on the bit lines, and the bit lines are in contact with the second source/drain doped area.

In an embodiment, a material of the bit lines BL includes, but is not limited to, a metal-doped semiconductor material, such as metal-doped silicon, metal-doped germanium, and metal-doped silicon germanium. In a specific embodiment, the substrate 20 is Si substrate. The material of the bit lines BL includes metal silicide, such as cobalt silicide (CoSiₓ), titanium silicide (TiSiₓ), and nickel silicide (NiSiₓ).

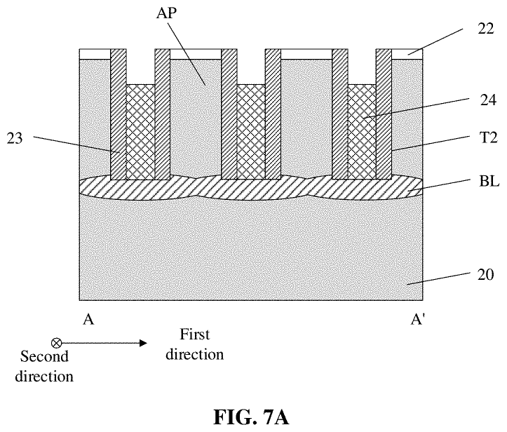

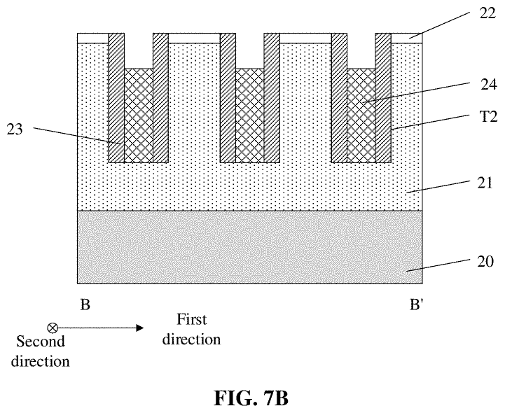

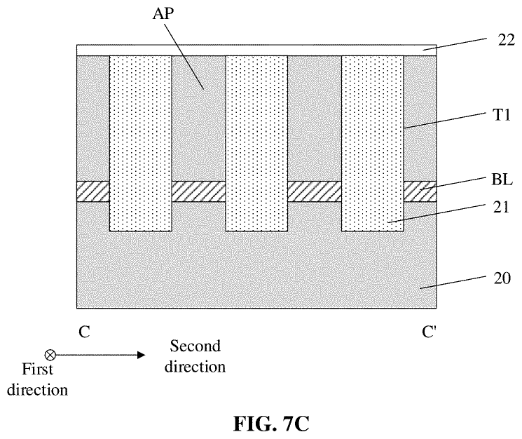

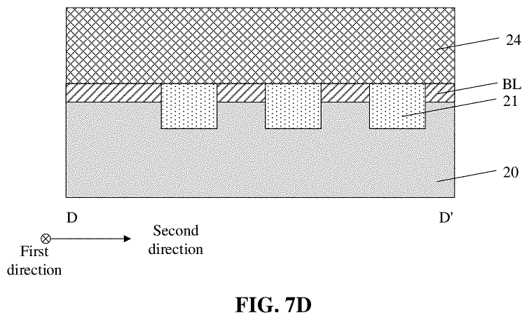

Next, S104 is performed; sacrificial layers 24 are deposited in the second grooves T2. The sacrificial layers 24 are sandwiched between the second dielectric layers 23, as shown in FIGS. 7A to 7D.

Each of the sacrificial layers 24 extends in the second direction, and has a uniform width and height in the extending direction. In some embodiments, the upper surface of the sacrificial layers 24 is lower than the upper surface of the second dielectric layers 23. The sacrificial layers 24 extend to the bottoms of the second grooves T2 in a direction perpendicular to the substrate 20. A material of the sacrificial layers 24 includes, but is not limited to, nitrides such as silicon nitride.

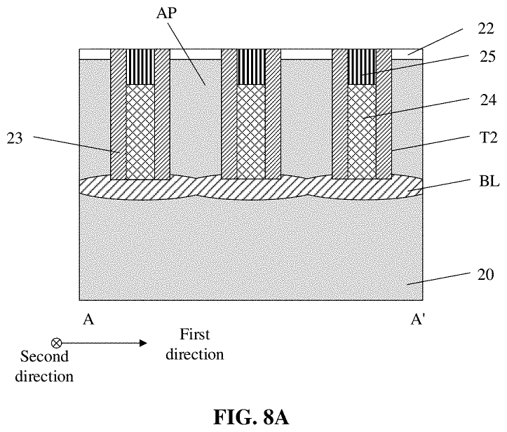

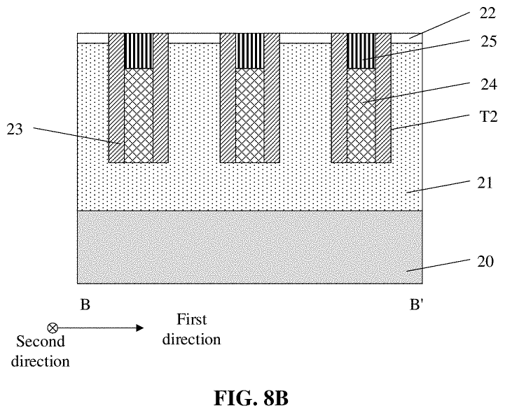

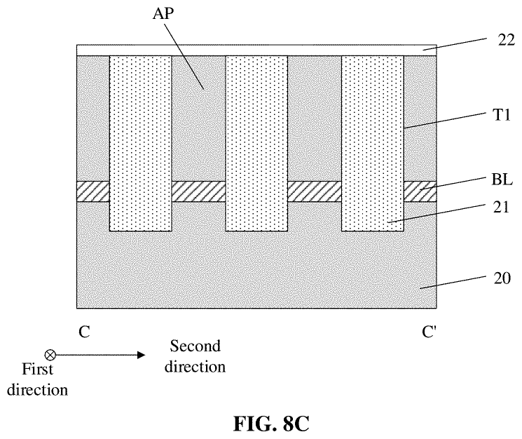

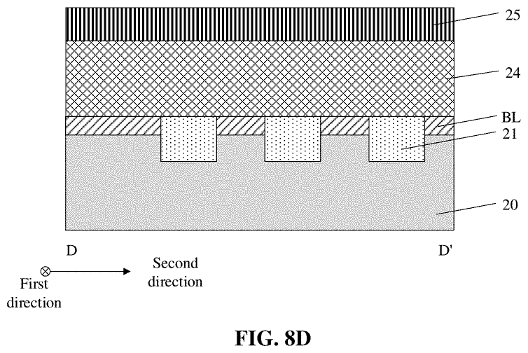

In an embodiment, after the sacrificial layers 24 are deposited in the second grooves T2, the method further includes: isolating layers 25 is deposited in the second grooves T2. The isolating layers 25 are located above the sacrificial layers 24, and two sides of each isolating layer 25 are adjacent to the second dielectric layers 23, as shown in FIGS. 8A to 8B. The isolating layers 25 are made of an insulating material, and configured to isolate the adjacent active columns AP.

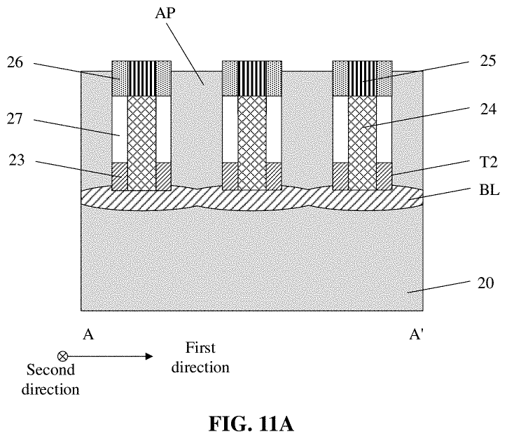

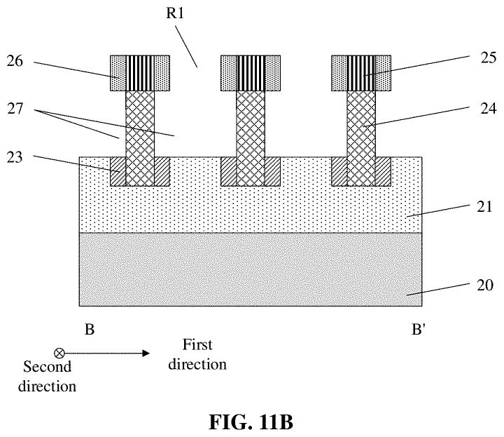

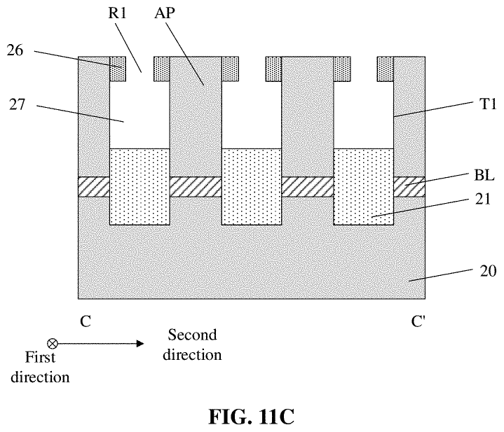

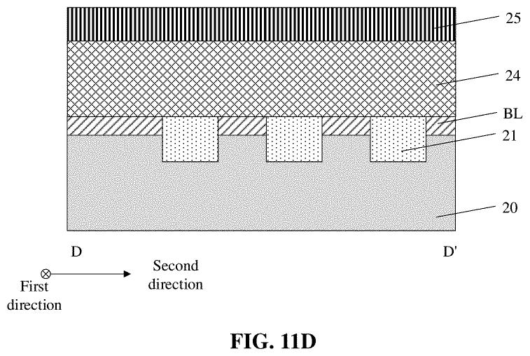

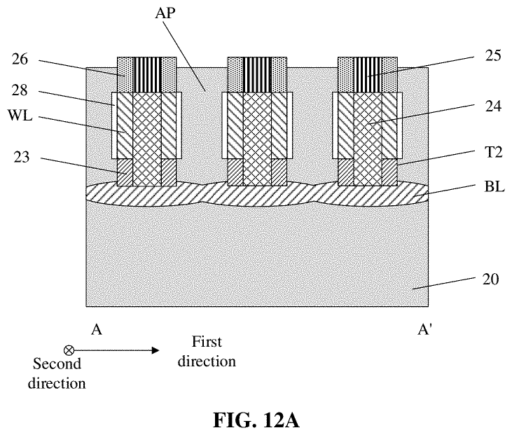

Next, S105 is performed; part of the first dielectric layer 21 and part of the second dielectric layer 23 are removed to form multiple hole structures 27 extending in the second direction. The hole structures 27 surround the active columns AP. Adjacent hole structures 27 are separated by the sacrificial layers 24, as shown in FIGS. 11A to 11D.

In an embodiment, before part of the first dielectric layer 21 and part of the second dielectric layer 23 are removed and multiple hole structures 27 extending in the second direction are formed, the method further includes the following operations.

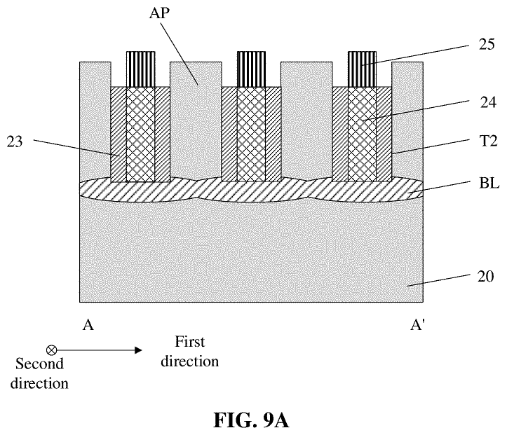

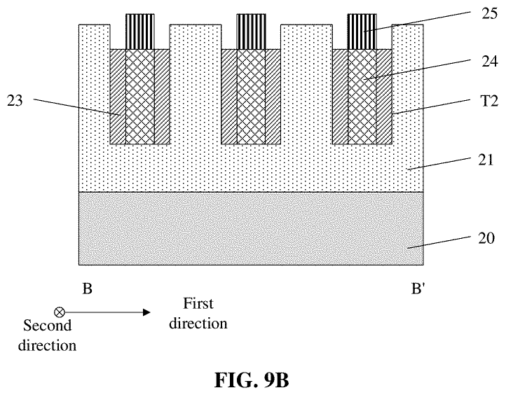

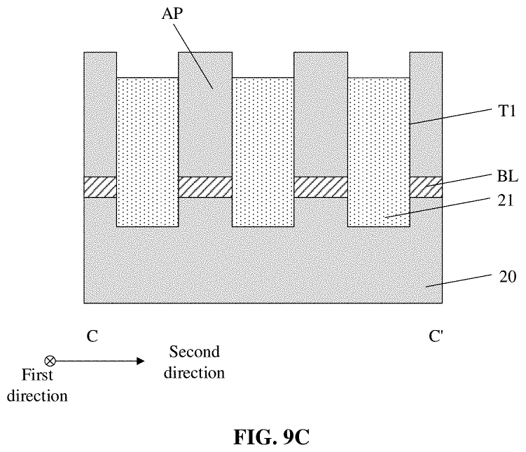

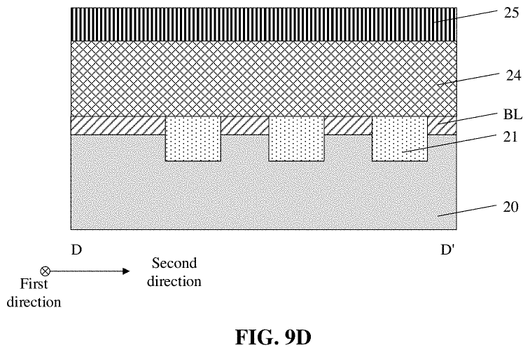

The first dielectric layer 21 and the second dielectric layer 23 with preset thicknesses are removed, to expose a side surface of the isolating layer 25 and partial side surface of the active column AP. The preset thickness is greater than or equal to the thickness of the isolating layer 25, as shown in FIGS. 9A to 9D.

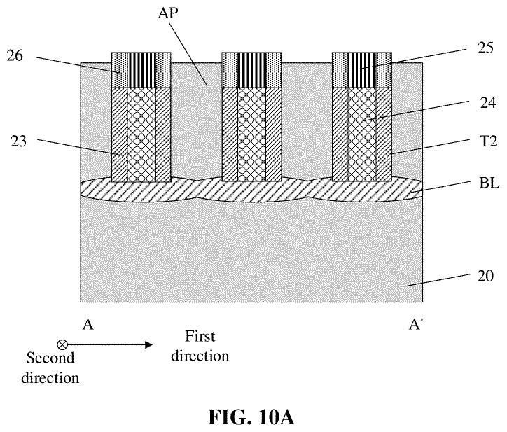

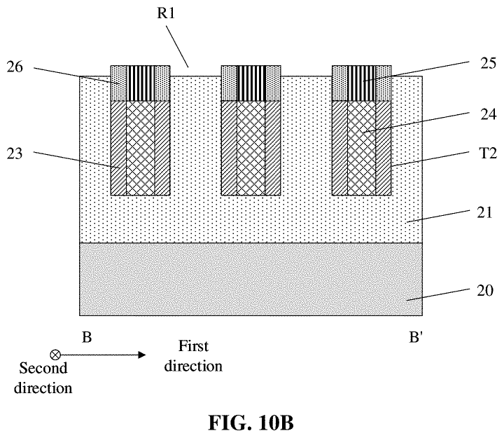

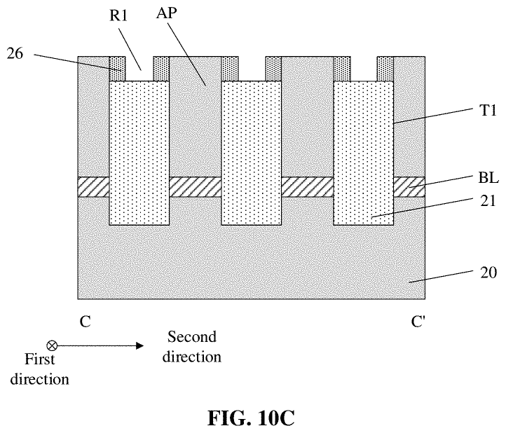

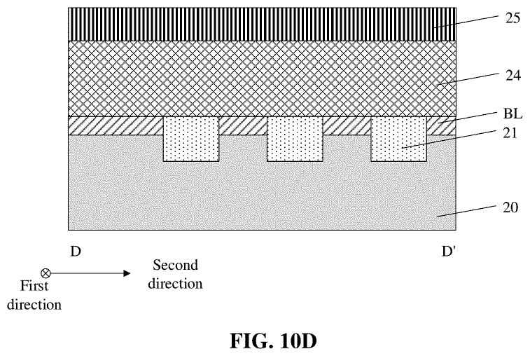

A third dielectric layer 26 is deposited on the side surface of the isolating layer 25 and the partial side surface of the active column AP, as shown in FIGS. 10A to 10D. The third dielectric layer 26 plays a role of supporting the isolating layer in the following process operations. A material of the third dielectric layer 26 includes, but is not limited to, nitrides such as silicon nitride.

Again, referring to FIGS. 9A to 9D, in a specific embodiment, the barrier layer 22 is also removed while the first dielectric layer 21 and the second dielectric layer 23 with preset thicknesses are removed.

Again, referring to FIGS. 10A to 10D, in an embodiment, the third dielectric layer 26 has multiple openings R1 exposing the first dielectric layer 21. An operation that multiple hole structures 27 extending in the second direction are formed includes: part of the first dielectric layer 21 and part of the second dielectric layer 23 are removed from the first openings R1 to form the hole structures 27 by a wet etching process, as shown in FIGS. 11A to 11D.

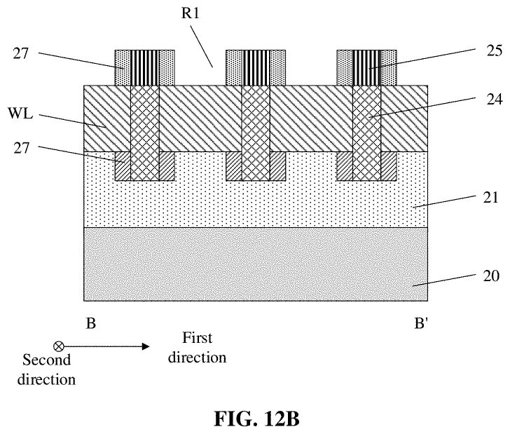

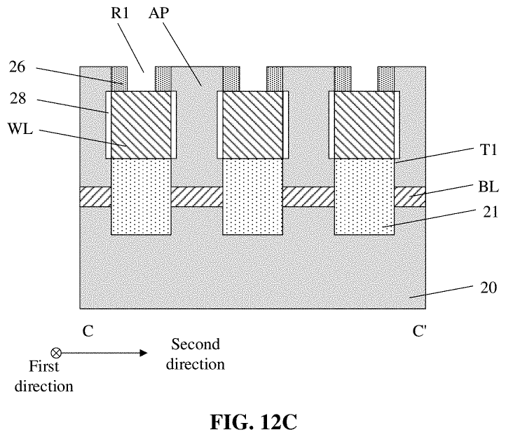

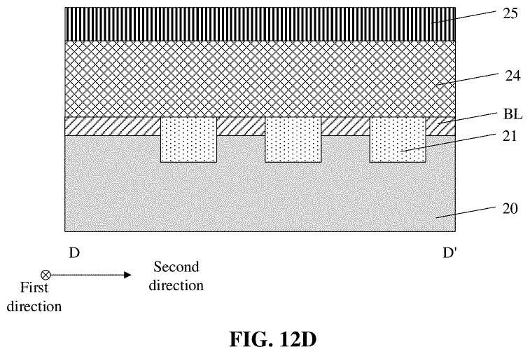

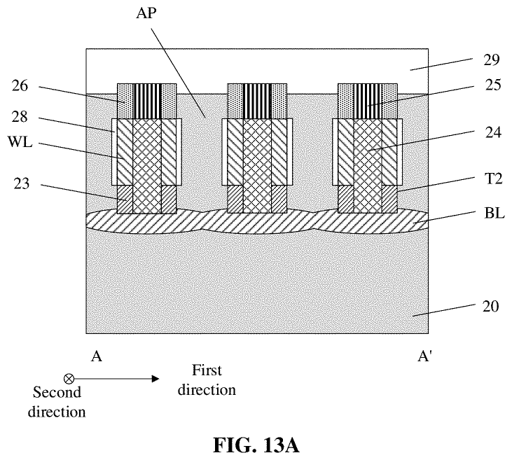

Next, S106 is performed; word lines WL are formed in the hole structures 27, as shown in FIGS. 12A to 12B.

A material of the word lines WL includes tungsten (W), copper (Cu), titanium (Ti), tantalum (Ta), titanium nitride (TiN), tantalum nitride (TaN), metal silicides, metal alloys, or any combination thereof. The word lines WL may be formed in the hole structures 27 by using processes such as CVD, Plasma Enhanced CVD (PECVD), Physical Vapor Deposition (PVD), ALD, electroplating, electroless plating, sputtering, and the like. Optionally, after the operation that the word lines WL are formed in the hole structures 27, a back-etching process is used, to make the upper surface of the word lines WL to be flush with the upper surface of the sacrificial layers 24 or lower than the upper surface of the sacrificial layers 24.

In an embodiment, the word lines WL have a uniform height in the extending direction. The upper surface of the word lines WL is flush with the upper surface of the sacrificial layers 24 or lower than the upper surface of the sacrificial layers 24. In a specific embodiment, a ratio of the height of the word lines WL to the height of the active columns AP ranges from ⅓ to ⅔.

In an embodiment, before the operation that word lines WL are formed in the hole structures 27, the method further includes the following operation. A gate dielectric layers 28 are formed on the surface of the active columns AP surrounded by the hole structures 27. The gate dielectric layers 28 are configured to isolate the word lines WL and the active columns AP. A material of the gate dielectric layers 28 includes, but is not limited to, oxides such as silicon oxide.

In a specific embodiment, the gate dielectric layer 28 is formed by converting part of the active column AP into oxides by means of in situ thermal oxidation.

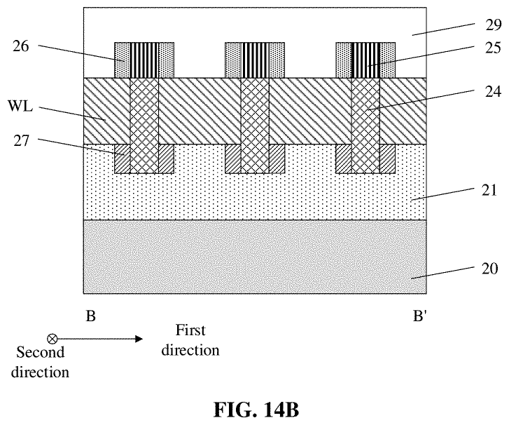

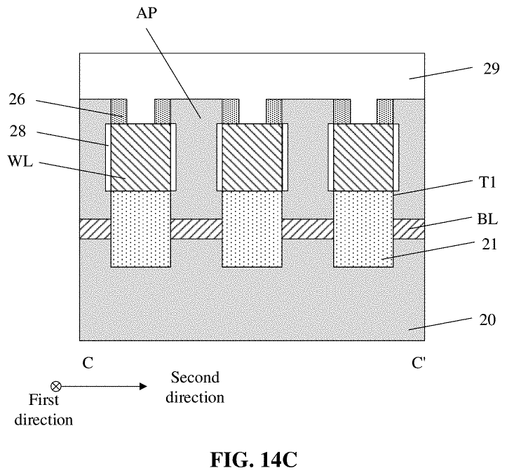

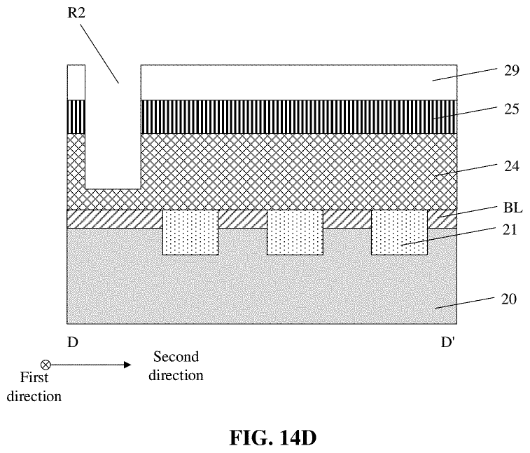

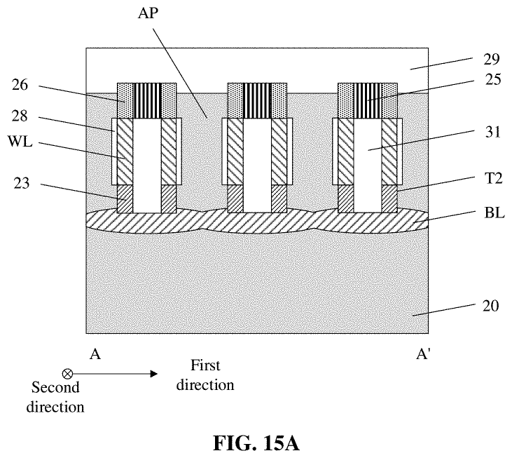

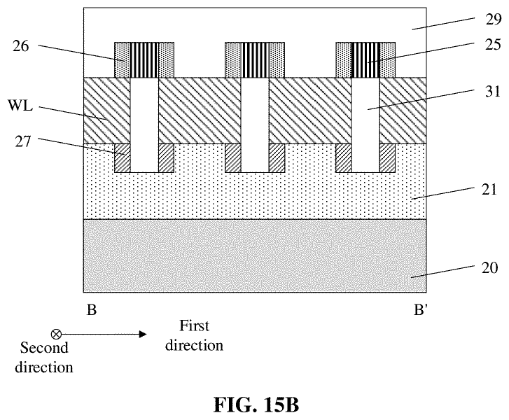

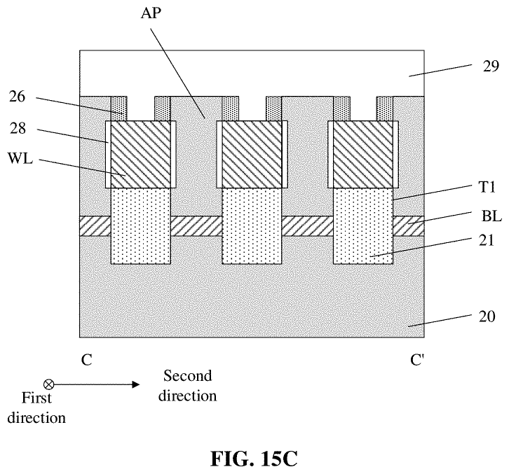

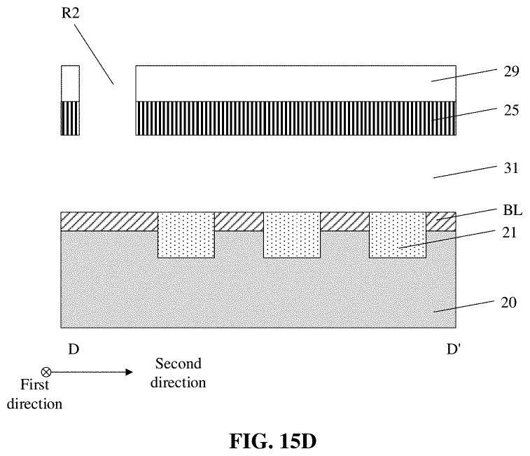

Finally, S107 is performed; the sacrificial layers 24 are removed to form air gaps 31 between the adjacent word lines WL, as shown in FIGS. 14A to 14D, and FIGS. 15A to 15D.

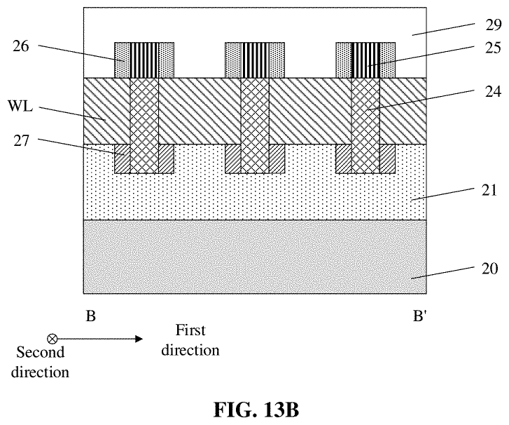

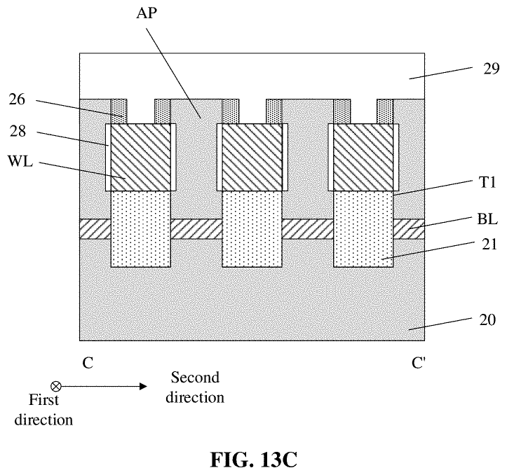

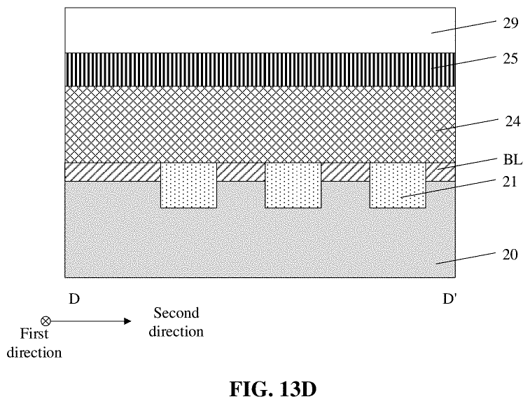

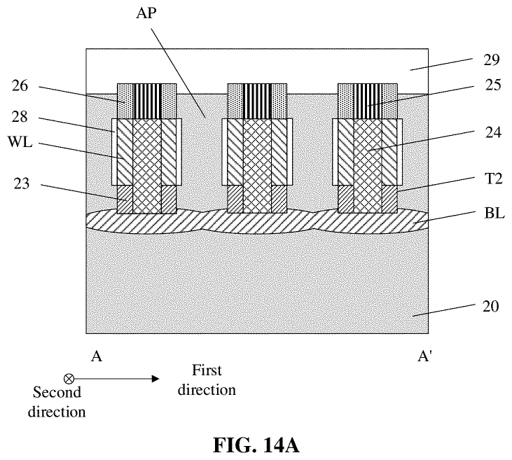

In an embodiment, as shown in FIGS. 13A to 13D, before the operation that the sacrificial layers 24 are removed, the method further includes: a fourth dielectric layer 29 is deposited on the substrate 20. The fourth dielectric layer 29 at least covers the upper surfaces of the substrate 20 and word lines WL. The fourth dielectric layer 29 is configured to protect the active columns AP and the word lines WL from being oxidized, nitrided, damaged, or contaminated in subsequent processes. A material of the fourth dielectric layer 29 includes, but is not limited to, oxides such as silicon oxide.

As shown in FIG. 2, the substrate 20 includes a storage area 20A and a peripheral area 20B. The second grooves T2 extend into the peripheral area 20B.

In an embodiment, the operation that the sacrificial layers 24 are removed includes: the sacrificial layers 24 are etched downward from the upper surface of the fourth dielectric layer 29, to form at least one second opening R2. The second opening R2 is located in the peripheral area 20B of the substrate 20, as shown in FIG. 14A to 14D. The sacrificial layers 24 are removed by a wet etching process, as shown in FIG. 15A to 15D.

Again, referring to FIGS. 14A to 14D, in a specific embodiment, the bottom of the second opening R2 extends into the sacrificial layers 24, to increase a contact area of an etching liquid and the sacrificial layers 24, so that the sacrificial layers 24 can be removed more quickly.

Again, referring to FIGS. 15A to 15D, in an embodiment, the air gaps 31 are located in the second groove T2 and extend in the second direction. An upper surface of the air gaps 31 is flush with the upper surface of the word lines WL or higher than the upper surface of the word lines WL. Each air gap 31 has a uniform width and height in the extending direction.

In conclusion, according to the design of the embodiments of the disclosure, the air gaps are formed between the adjacent word lines. The air gaps have a relatively low dielectric constant, which can reduce a parasitic capacitance between the adjacent word lines in the semiconductor structure, so that the performance of the semiconductor structure can be improved finally.

An embodiment of the disclosure further provides a semiconductor structure, as shown in FIGS. 15A to 15D, including a substrate 20, a first dielectric layer 21, a second dielectric layer 23, an air gap 31, and multiple word lines WL.

The substrate 20 includes multiple first grooves T1 extending in the first direction and multiple second grooves T2 extending in the second direction. The first grooves T1 and the second grooves T2 are intersected with each other, and define multiple discrete active columns AP in the substrate 20.

The first dielectric layer is located at the bottom of first grooves T1.

The second dielectric layer covers sidewalls at a bottom of each second groove T2.

The air gaps are located in the second grooves T2.

The multiple word lines WL extend in the second direction, and are located in the first grooves T1 and the second grooves T2. The word lines WL surround the active columns AP and cover upper surfaces of the first dielectric layer 21 and the second dielectric layer 23.

The adjacent word lines WL are separated by the air gaps 31.

The substrate may be a semiconductor substrate, and may include at least one elementary semiconductor material (for example, a silicon (Si) substrate, or a germanium (Ge) substrate), at least one III-V compound semiconductor material, at least one II-VI compound semiconductor material, at least one organic semiconductor material, or other semiconductor materials known in the art. In a specific embodiment, the substrate is the Si substrate. The substrate may or may not be doped.

In an embodiment, the multiple first grooves T1 are equidistantly distributed in the substrate 20, and the multiple second grooves T2 are also equidistantly distributed in the substrate 20.

In an embodiment, the depth of the second grooves T2 is less than the depth of the first grooves T1. That is to say, the bottom surface of the second grooves T2 is higher than bottom surface of the first grooves T1.

In an embodiment, the first direction is perpendicular to the second direction, but is not limited thereto. In other embodiments, an acute angle is formed between the first direction and the second direction.

In an embodiment, the first dielectric layer 21 located at the bottom of the first grooves T1 has different heights in the extending direction, as shown in FIG. 15B. In some embodiments, a material of the first dielectric layer 21 includes oxides, such as silicon oxide.

In an embodiment, the semiconductor structure further includes multiple bit lines BL extending in the first direction. The bit lines BL are formed by doping the bottom of the second grooves T2. The adjacent bit lines BL are separated by the first dielectric layer 21.

Specifically, a material of the bit lines BL includes, but is not limited to, a metal-doped semiconductor material, such as metal-doped silicon, metal-doped germanium, and metal-doped silicon germanium. In a specific embodiment, the substrate 20 is Si substrate. The material of the bit lines BL includes metal silicide, such as cobalt silicide (CoSiₓ), titanium silicide (TiSiₓ), and nickel silicide (NiSiₓ).

In an embodiment, the semiconductor structure further includes a first source/drain doped area (not shown) and a second source/drain doped area (not shown). The first source/drain doped area (not shown) is located on a top of the active column AP. The second source/drain doped area (not shown) is located at a bottom of the active column AP. The first source/drain doped area (not shown) and the second source/drain doped area (not shown) may have a same conductive type. In an embodiment, the second source/drain doped area (not shown) extends from the lower surface of the substrate 20 to the active column AP. At least part of the second source/drain doped area (not shown) is located on the bottom surface of the second groove T2. That is to say, at least part of the second source/drain doped area (not shown) is located on the bit lines BL, and the bit lines BL are in contact with the second source/drain doped area (not shown).

In an embodiment, the word line WL has a uniform height in the extending direction. A ratio of the height of the word lines WL to the height of the active columns AP ranges from ⅓ to ⅔. A material of the word lines WL includes tungsten (W), copper (Cu), titanium (Ti), tantalum (Ta), titanium nitride (TiN), tantalum nitride (TaN), metal silicides, metal alloys, or any combination thereof.

In an embodiment, the semiconductor structure further includes gate dielectric layers 28. The gate dielectric layers 28 are located between the word lines WL and the active columns AP, and configured to separate the word lines WL and the active columns AP. In a specific embodiment, the gate dielectric layer 28 is formed by converting part of the active column AP into the oxides by means of in situ thermal oxidation. A material of the gate dielectric layers 28 may specifically be silicon oxide.

In an embodiment, the air gaps 31 extend in the second direction. An upper surface of the air gaps 31 is flush with an upper surface of word lines WL or higher than the upper surface of the word lines WL. Each air gap 31 has a uniform width and height in an extending direction. In a specific embodiment, the air gaps 31 extend to the bottom of the second groove T2 in the direction perpendicular to the substrate 20. The second dielectric layers 23 are located on two sides of the each air gap 31, and configured to separate the air gaps 31 and the active columns AP. In some embodiments, the second dielectric layers 23 may be made of oxides, specifically, silicon oxide.

The air gaps are located between the adjacent word lines. The air gaps have a relatively low dielectric constant, which can reduce a parasitic capacitance between the adjacent word lines in the semiconductor structure, so that the performance of the semiconductor structure can be improved finally.

In an embodiment, the semiconductor structure further includes an isolating layer 25. The isolating layers 25 are located in the second grooves T2 and above the air gaps 31. The lower surface of the isolating layers 25 may be flush with the upper surface of the word lines WL or higher than the upper surface of the word lines WL. The isolating layers 25 are made of an insulating material.

In an embodiment, the semiconductor structure further includes third dielectric layers 26. The third dielectric layers are located above the word lines WL and cover side surfaces of the isolating layers 25 and partial side surfaces of the active columns AP. A lower surface of the third dielectric layers 26 is flush with the lower surface of the isolating layers 25 or lower than the lower surface of the isolating layers 25. A material of the third dielectric layers 26 includes, but is not limited to, nitrides such as silicon nitride. The isolating layers 25 and the third dielectric layer 26 are configured to isolate the adjacent active columns AP.

In an embodiment, the semiconductor structure further includes a fourth dielectric layer 29. The fourth dielectric layer 29 at least covers the upper surface of the substrate 20 and the word lines WL, and is configured to protect the active columns AP and the word lines WL from being oxidized, nitrided, damaged, or contaminated. The fourth dielectric layer 29 includes, but is not limited to, oxides such as silicon oxide.

The above are only preferred embodiments of the disclosure, and are not used to limit the scope of protection of the disclosure. Any modifications, equivalent replacements and improvements and the like made within the spirit and principle of the disclosure shall be included within the scope of protection of the disclosure.

What is claimed is:

1. A method for manufacturing a semiconductor structure, comprising:
forming a plurality of first grooves filled with a first dielectric layer and extending in a first direction in a substrate;
forming a plurality of second grooves extending in a second direction in the substrate and the first dielectric layer, the second grooves and the first grooves being intersected and defining a plurality of discrete active columns in the substrate;
depositing second dielectric layers on sidewalls of the second grooves;
depositing sacrificial layers in the second grooves, the sacrificial layers being sandwiched between the second dielectric layers;
removing part of the first dielectric layer and part of each of the second dielectric layers, and forming a plurality of hole structures extending in the second direction, the hole structures surrounding the active columns, and adjacent hole structures being separated by the sacrificial layers;
forming word lines in the hole structures; and
removing the sacrificial layers to form air gaps between adjacent word lines.

2. The method of claim 1, wherein the first grooves define the substrate into a plurality of structure bodies extending in the first direction; and before the forming a plurality of second grooves, the method further comprises:
forming a first source/drain doped area and a second source/drain doped area on a top and a bottom of the structure bodies respectively by subjecting the substrate with ion implantation.

3. The method of claim 1, wherein after the depositing second dielectric layers on sidewalls of the second grooves, the method further comprises:
doping the substrate from a bottom of the second grooves to form a plurality of bit lines extending in the first direction, adjacent bit lines being separated by the first dielectric layer.

4. The method of claim 1, wherein after the depositing sacrificial layers in the second grooves, the method further comprises:
depositing isolating layers in the second grooves, the isolating layers being located above the sacrificial layers, and two sides of each of the isolating layers being adjacent to the second dielectric layers.

5. The method of claim 4, wherein before the removing part of the first dielectric layer and part of each of the second dielectric layers, and forming a plurality of hole structures extending in the second direction, the method further comprises:
removing the first dielectric layer and the second dielectric layers with preset thicknesses to expose a side surface of the isolating layers and partial side surface of each of the active columns, wherein the preset thickness is greater than or equal to thickness of the isolating layers; and
depositing third dielectric layers on the side surface of the isolating layers and the partial side surface of each of the active columns.

6. The method of claim 5, wherein the third dielectric layers have a plurality of first openings exposing the first dielectric layer; and the forming a plurality of hole structures extending in the second direction comprises: removing part of the first dielectric layer and part of each of the second dielectric layers from the first openings to form the hole structures by a wet etching process.

7. The method of claim 1, wherein before the forming word lines in the hole structures, the method further comprises:
forming gate dielectric layers on a surface of the active columns surrounded by the hole structures.

8. The method of claim 1, wherein before the removing the sacrificial layers, the method further comprises:
depositing a fourth dielectric layer on the substrate, the fourth dielectric layer at least covering upper surfaces of the substrate and the word lines.

9. The method of claim 8, wherein the substrate comprises a storage area and a peripheral area; and the removing the sacrificial layers comprises:
etching the sacrificial layers downward from an upper surface of the fourth dielectric layer to form at least one second opening, the second opening being located at the peripheral area; and
removing the sacrificial layers by a wet etching process.

10. A semiconductor structure, comprising:
a substrate, comprising a plurality of first grooves extending in a first direction and a plurality of second grooves extending in a second direction, the first grooves and the second grooves being intersected and defining a plurality of discrete active columns in the substrate;
a first dielectric layer, located at a bottom of first grooves;
second dielectric layers, covering sidewalls at a bottom of the second grooves;
air gaps, located in the second grooves; and
a plurality of word lines extending in the second direction, located in the first grooves and the second grooves, the word lines surrounding the active columns and covering upper surfaces of the first dielectric layer and the second dielectric layers,
wherein adjacent word lines are separated by the air gaps.

11. The semiconductor structure of claim 10, wherein the air gaps extend in the second direction, an upper surface of the air gaps is flush with an upper surface of the word lines or higher than the upper surface of the word lines, and each of the air gap has a uniform width and height in an extending direction.

12. The semiconductor structure of claim 10, wherein the air gaps extend to the bottom of the second grooves in a direction perpendicular to the substrate, and the second dielectric layers are located at two sides of each of the air gaps.

13. The semiconductor structure of claim 10, further comprising isolating layers, wherein the isolating layers are located in the second grooves and above the air gaps.

14. The semiconductor structure of claim 13, further comprising third dielectric layers, wherein the third dielectric layers are located above the word lines and cover a side surface of the isolating layers and a partial side surface of the each of the active columns.

15. The semiconductor structure of claim 10, further comprising a fourth dielectric layer, wherein the fourth dielectric layer at least covers upper surfaces of the substrate and the word lines.

16. The semiconductor structure of claim 10, further comprising gate dielectric layers, wherein the gate dielectric layers are located between the word lines and the active columns.

17. The semiconductor structure of claim 10, further comprising a plurality of bit lines extending in the first direction, wherein the bit lines are formed by doping the bottom of the second grooves, and adjacent bit lines are separated by the first dielectric layer.

18. The semiconductor structure of claim 10, further comprising a first source/drain doped area and a second source/drain doped area, wherein the first source/drain doped area is located at a top of the active columns, and the second source/drain doped area is located at a bottom of the active columns.
